(19) United States
(12) Patent Application Publication
(10) Pub. No.: US 2010/0228507 A1
(43) Pub. Date: Sep. 9, 2010

(54) TRACE DEVICE AND TRACE METHOD FOR FAILURE ANALYSIS

(75) Inventors: Yuka HOSOKAWA, Kawasaki (JP); Takashi Yamamoto, Kawasaki (JP); Toshikazu Ueki, Kawasaki (JP); Kenta Sato, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/714,939

(22) Filed: Mar. 1, 2010

(30) Foreign Application Priority Data
Mar. 4, 2009 (JP) 2009-51074

(51) Int. Cl. G06F 19/00; G01R 31/00

(52) U.S. Cl. 702/58; 702/117

(57) ABSTRACT

A trace device for tracing data in an LSI includes a trace data storing unit that stores trace data, a trace target determination unit that determines whether to store trace data of one of a plurality of trace targets in the trace data storing unit based on an operating state of a system including the LSI and based on a failure occurrence report reported from any of the trace targets in response to an occurrence of an error in the trace target residing in the LSI and a trace target selection unit that selects the trace data to be stored in the trace data storing unit out of the trace data from the plurality of trace targets based on the determining by the trace target determination unit, and stores the selected trace data in the trace data storing unit.

### CROSS-REFERENCE TO RELATED APPLICATIONS

This application is based upon and claims priority to prior Japanese Patent Application No. 2009-51074 filed on Mar. 4, 2009 in the Japan Patent Office, the entire contents of which are incorporated herein by reference.

### FIELD

The present invention relates to a trace device and a trace method for failure analysis.

### BACKGROUND

There is known a technique of a failure analysis in which upon detection of a failure such as an error or the like in a Large Scale Integrated circuit (LSI), the failure analysis is performed by using data stored in a memory during the LSI's operation as a conventional technique.

FIG. 7 illustrates a configuration example of an information processing apparatus on which a plurality of LSIs is provided. The information processing apparatus includes a plurality of system boards (SB), a plurality of I/O control units (IOU), and so on. These system boards and I/O control units are coupled with data cross bars (indicated as “DATA CROSSBAR” in FIG. 7) and address cross bars (indicated as “ADDRESS CROSSBAR” in FIG. 7).

Each of the system boards (SB) includes memory controllers (LDX), Central Processing Units (CPU), memories (DIMM), a CPU-memory controller (FLN), firmware hubs (FWH), and so on.

Each of the I/O control units (IOU) includes I/O controllers (FLI), I/O controller hubs (ICH6), and so on.

A service processor (SVP illustrated as “MMB” in FIG. 7) performs control, monitoring, partition-management, system initialization, and so on in the information processing apparatus.

Each of the LSIs including, for example, the memory controller, the CPU-memory controller, and the I/O controller, includes a trace function for performing the failure analysis of the LSI in the information processing apparatus discussed above.

FIG. 8 illustrates an example of a block diagram of an LSI.

An LSI 800 includes a system core circuit 801, a write control circuit 803, a read control circuit 804, and a trace data memory 805. The system core circuit 801 is provided with a core circuit error detection unit 802 that detects an error in the system core circuit 801. The trace data memory 805 is a memory that stores trace data. A service processor 806 is a control unit that controls an entire system of the information processing apparatus. The service processor 806 corresponds to an MMB in FIG. 7.

The write control circuit 803 outputs a write control signal 811 to the trace data memory 805 based on a write direction signal 809 which directs writing of the trace data outputted from the service processor 806 to control writing of data on a system core circuit trace data bus 807 to the trace data memory 805.

The read control circuit 804 outputs a read control signal 812 to the trace data memory 805 based on a read direction signal 810 which directs reading of the trace data outputted from the service processor 806 to control reading of the trace data to a read trace data bus 808 from the trace data memory 805.

The write direction signal 809 which directs the writing of the trace data is sent from the service processor 806 to the write control circuit 803 and the trace data on the system core circuit 801 is stored in the trace data memory 805 through the system core circuit trace data bus 807 which is a trace data bus.

Upon occurrence of an error on the system core circuit 801, the core circuit error detection unit 802 detects the error and reports an error report signal 813 to the service processor 806. The service processor 806 sends write direction signal 809 as a direction signal to the write control circuit 803 to stop the writing to the trace data memory 805. In response thereto, the write control signal 811 to stop the writing of data is sent from the write control circuit 803 to the trace data memory 805 to stop the writing of the trace data. Furthermore, the service processor 806 sends the read direction signal 810 to the read control circuit 804 to direct the reading, and the read control circuit 804 outputs the read control signal 812 to read the trace data from the trace data memory 805. The service processor 806 performs the failure analysis using the trace data read from the trace data memory 805, so that a suspected failure location is detected.

As disclosed above, log collection, in other words “tracing,” is performed in the LSI as discussed above. FIG. 9 illustrates data in association with a trace target according to the LSIs.

As illustrated in FIG. 9, there is no change in the trace target in the LSI during a system initialization (note that the “system” here means, for example, the information processing apparatus) and during a normal system operation. That is to say, the trace target for system log collection is always the same during the system initialization and during the normal system operation. Consequently, the trace target that is traced remains unchanged regardless of the location of the circuit that is operating upon occurrence of the error.

Patent Document 1 discusses a trace device as the trace target in which a change in tracing conditions during a trace operation is possible with trigger settings made in a sequential manner by writing an address, serving as the trigger for tracing, into a read only memory (ROM) in advance for the purpose of detecting that output data of an LSI satisfies a given condition.

Also, a high-speed interface especially between LSIs or chipsets has been provided in recent years by virtue of high-speed processing in the information processing apparatus. For example, a PCI Express (Peripheral Component Interconnect Express: serial transfer interface for PCs replacing the PCI bus) or the like achieves the serial transmission of 5 Gbps. After power-on of the information processing apparatus, the PCI Express performs training or negotiation on an interface unit and moves into the normal system operation after the initialization operation in which a Link-up is established. The circuit thereof has a layer structure so that the layer in operation during the initialization or during the normal system operation is different depending thereon.

For this reason, when it comes to a transmission circuit, such as the PCI Express or the like, it is highly possible that the failures during the initialization mainly occur in the physical layers and the failures during the normal system operation mainly occur in link layers. In consequence, when a failure has occurred during the initialization, tracing on a physical layer circuit is performed, and on the other hand, when a failure has occurred during the normal system operation, tracing on a link layer circuit is performed. That is to say, it is desirable to collect trace data effective for subsequent failure analysis.
[Paten Document 1] Japanese Laid-Open Patent Publication No. 1-201740

### SUMMARY

According to an aspect of the invention, a trace device for tracing data in an LSI includes a trace data storing unit that stores trace data, a trace target determination unit that determines whether to store trace data of one of a plurality of trace targets in the trace data storing unit based on an operating state of a system including the LSI and based on a failure occurrence report reported from any of the trace targets in response to an occurrence of an error in the trace target residing in the LSI and a trace target selection unit that selects the trace data to be stored in the trace data storing unit out of the trace data from the plurality of trace targets based on the determining by the trace target determination unit, and stores the selected trace data in the trace data storing unit.

### BRIEF DESCRIPTION OF THE DRAWINGS

FIG. 1 illustrates a block diagram of an information processing apparatus according to an embodiment of the present invention;

FIG. 2 illustrates a block diagram of an LSI according to the embodiment of the present invention;

FIG. 3 is a diagram explaining a trace target according to the embodiment of the present invention;

FIG. 4 is a diagram depicting a configuration of a part related to trace target switching according to the embodiment of the present invention;

FIG. 5 is a diagram depicting a memory format of a trace data memory according to the embodiment of the present invention;

FIG. 6 illustrates a flowchart of trace processing according to the embodiment of the present invention;

FIG. 7 illustrates a block diagram of a configuration example of an information processing apparatus;

FIG. 8 illustrates a block diagram depicting an example of a conventional LSI; and

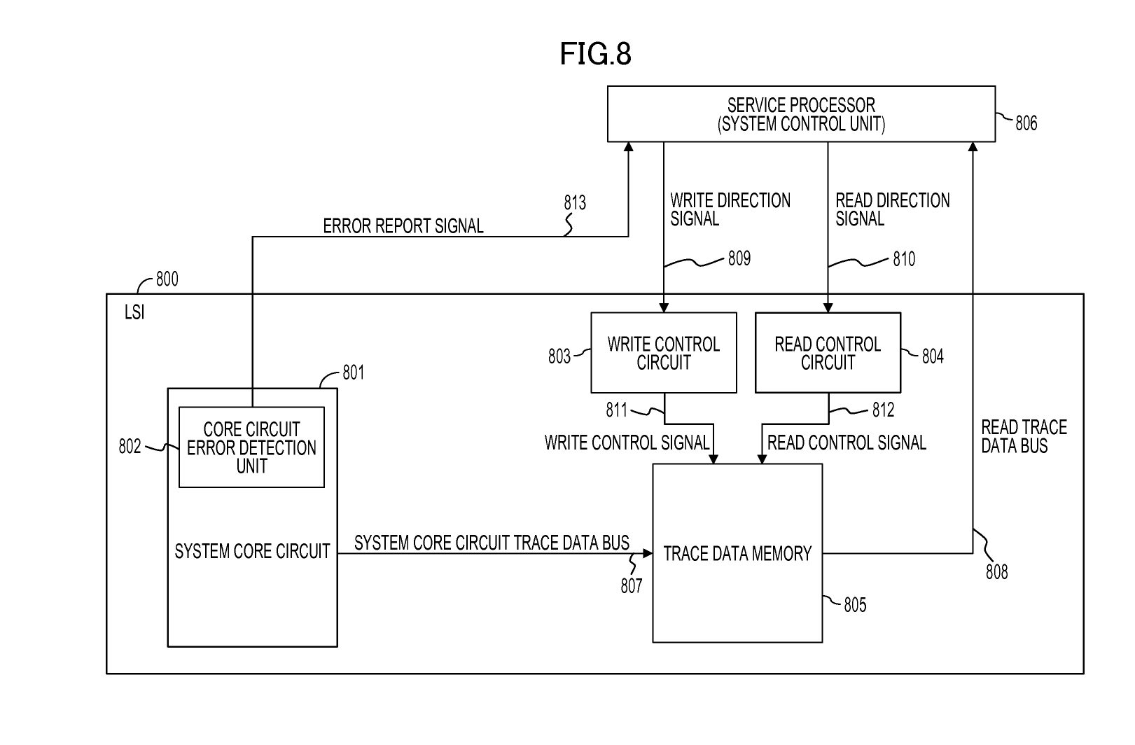

FIG. 9 is a diagram explaining a trace target of the conventional LSI.

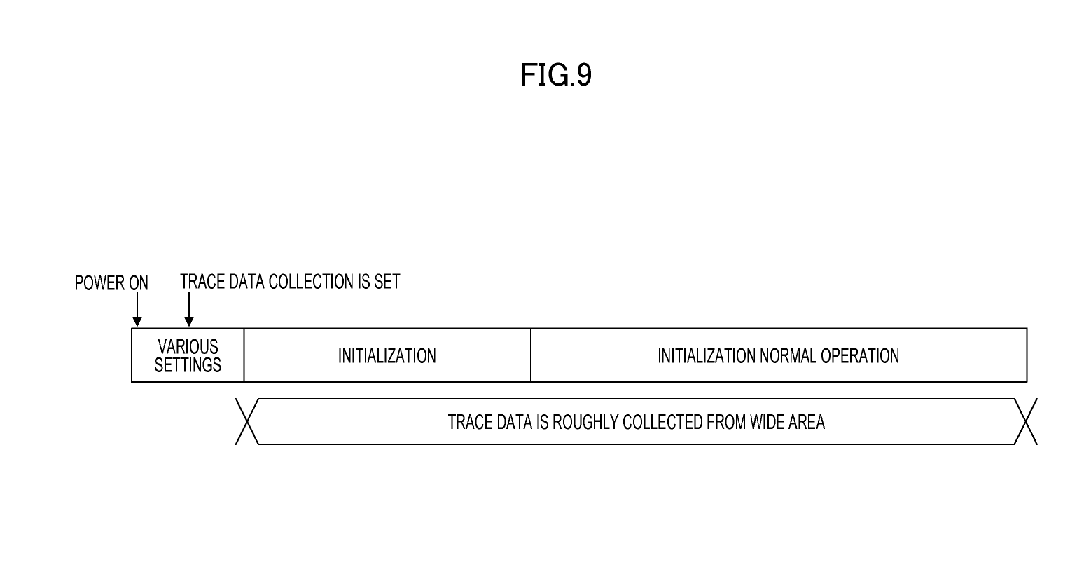

### DESCRIPTION OF EMBODIMENTS

Hereinafter, an embodiment of the present invention will be disclosed in detail with reference to attached drawings.

The embodiment hereinafter disclosed is just one example of the present invention and is disclosed in enough detail to enable those skilled in the art to practice the invention. In addition, it may be understood that the present invention may be practiced in a variety of ways and various structural and/or logical modifications or the like may be made without departing from the scope and spirit of the present invention.

### Embodiment

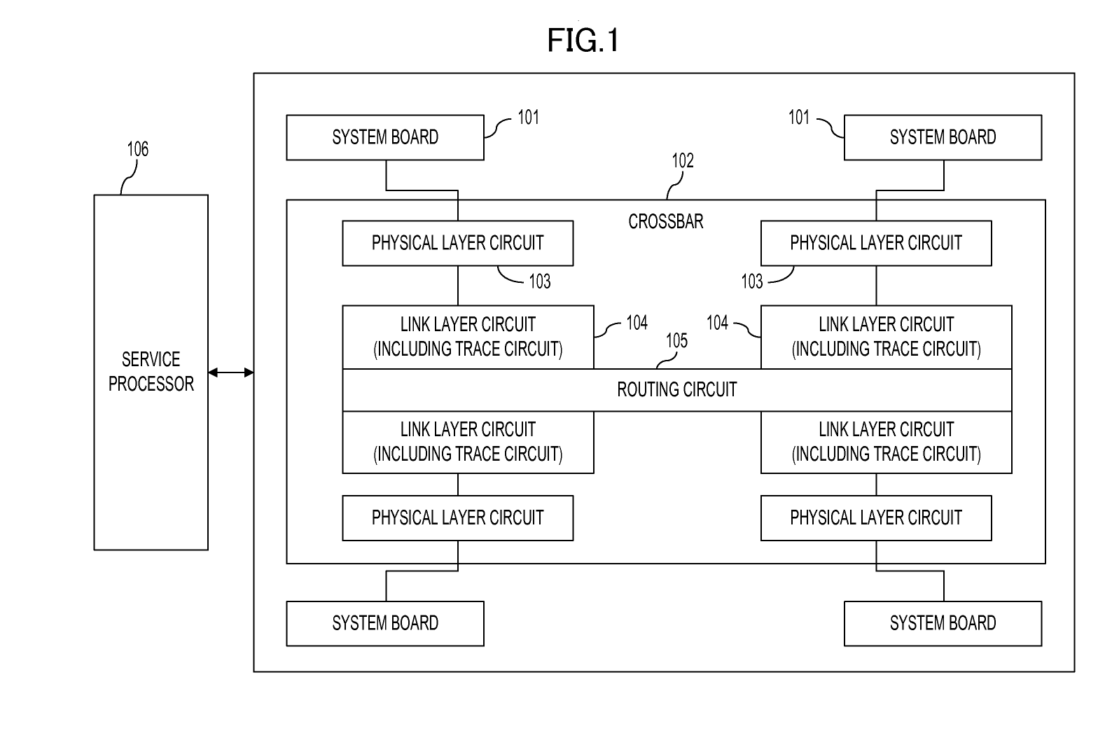

FIG. 1 illustrates a block diagram of an information processing apparatus according to an embodiment.

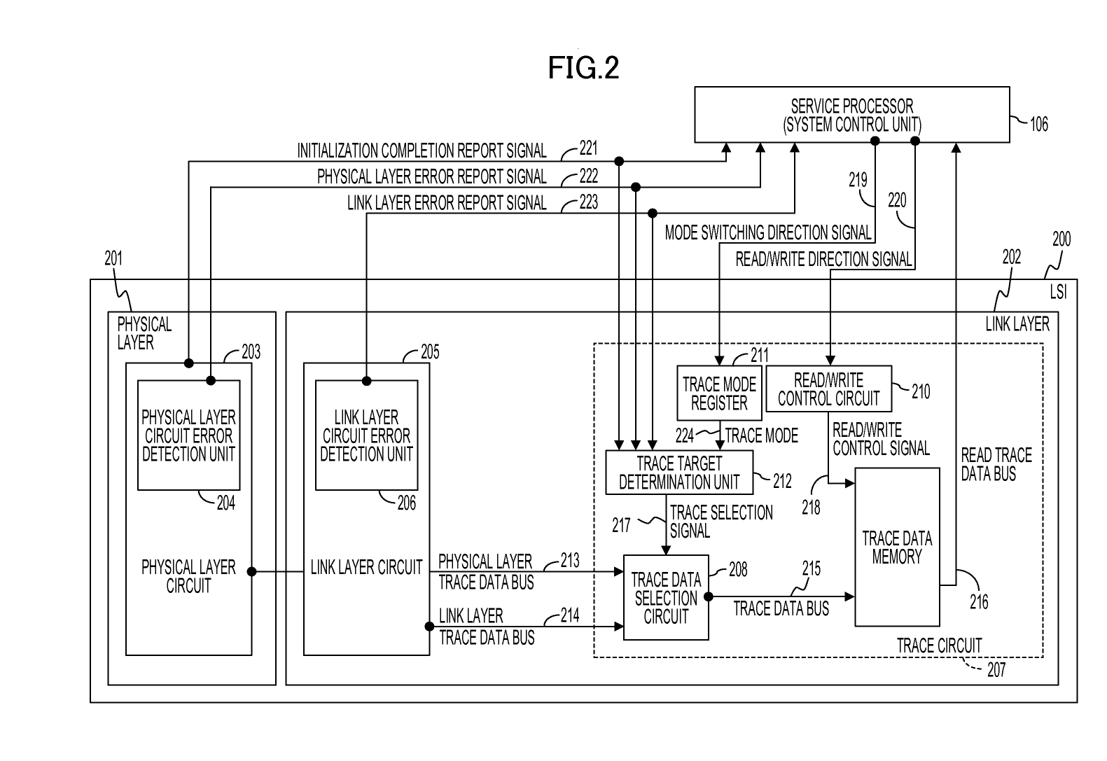

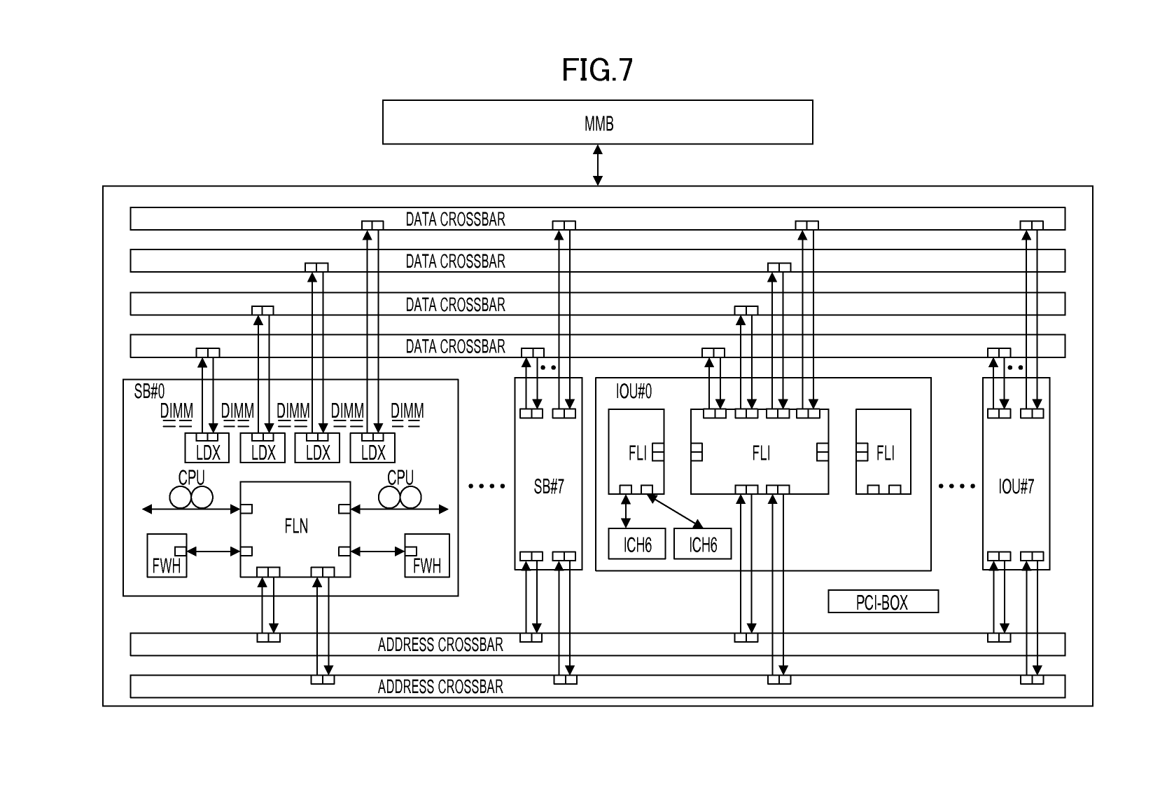

System boards 101 are coupled by using a cross bar 102 in the information processing apparatus according to the embodiment. A transmission circuit is formed by including physical layer circuits 103 and link layer circuits 104 therein. The link layer circuits 104 include a trace circuit (illustrated in FIG. 2) that collects trace data therein. Note that FIG. 1 conceptually corresponds to FIG. 7. FIG. 1 focuses on the cross bar 102. Thus, the correspondence relationship between FIG. 1 and FIG. 7 may be complicated due to the depiction in which the physical circuits 103 and the link layer circuits 104, serving as transmission paths inside a plurality of LSIs included in the system board, are depicted over the cross bar 102.

FIG. 2 illustrates a block diagram of an LSI according to the embodiment. An LSI 200 includes a physical layer circuit 203, a link layer circuit 205, and a trace circuit 207. The physical layer circuit 203 includes a physical layer circuit error detection unit 204 and the link layer circuit 205 includes a link layer circuit error detection unit 206. The physical layer circuit error detection unit 204 and the link layer circuit error detection unit 206 are circuits that detect failures in the respective circuits.

The trace circuit 207 includes a trace mode register 211, a trace data selection circuit 208, a trace target determination unit 212, a trace data memory 209, and a read/write control circuit 210. The trace mode register 211 stores trace modes used in selecting the trace data. The trace data selection circuit 208 selects a data bus from the physical layer circuit 203 and from the link layer circuit 205 each of which is a trace target. The trace target determination unit 212 sends a trace selection signal 217 to the trace data selection circuit 208 as a signal for switching the trace targets. The trace data memory 209 stores the trace data. The read/write control circuit 210 controls reading from and writing to the trace data memory 209.

A service processor 106 illustrated in FIG. 2 serves as a control unit that controls a system of the information processing apparatus or the like. The service processor 106 illustrated in FIG. 2 is the same as that illustrated in FIG. 1.

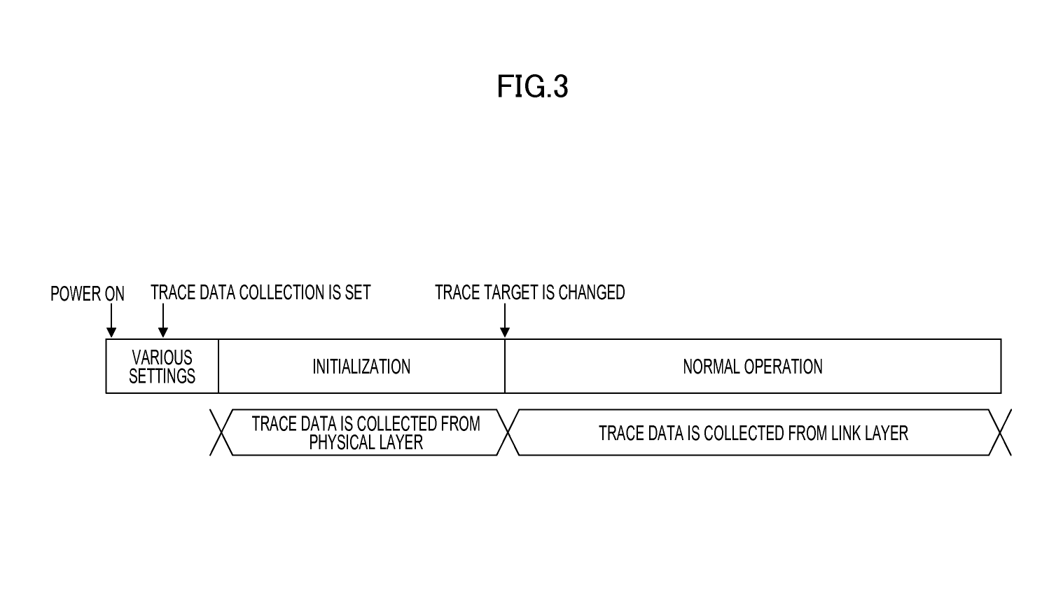

Hereinafter, an operation of the LSI 200 in FIG. 2 will be disclosed in which a state of the system, which includes the LSI 200, is represented by, for example, the information processing apparatus executing a system initialization subsequent to power activation thereof, and the state of the system moving into normal system operation after completion of the system initialization. After the power activation of the system, trace data collection settings are made during the system initialization (the timing thereof will be disclosed in FIG. 3). Then, a mode switching direction signal 219 is sent from the service processor 106 to the trace mode register 211, whereby values for setting the trace modes are stored in the trace mode register 211. Types of the trace modes will be disclosed below. Assume here that Mode 0 is set so that the physical layer circuit 203 is traced during the system initialization and the link layer circuit 205 is traced after completion of the system initialization.

In Mode 0, a physical layer trace data bus 213, in other words, a trace bus whose target is the physical layer circuit 203, is selected by the trace data selection circuit 208 during the system initialization, and the trace data is stored in the trace data memory 209 through a trace data bus 215.

Upon completion of the system initialization, an initialization completion report signal 221 is sent from the physical layer circuit 203 to the trace target determination unit 212. The trace selection signal 217 that includes information related to the trace target determined by the trace target determination unit 212 is sent to the trace data selection circuit 208. The trace data selection circuit 208 switches the trace target from the physical layer circuit 203 to the link layer circuit 205 based on the trace selection signal 217 disclosed above. That is to say, a link layer trace data bus 214 is selected by the trace data selection circuit 208 and the trace data is stored in the trace data memory 209 through the trace data bus 215.

During the normal system operation, in response to detection of an error by the physical layer circuit error detection unit 204, a physical layer error report signal 222 is sent to the trace target determination unit 212. The trace selection signal 217 that includes the information related to the trace target determined by the trace target determination unit 212 is sent to the trace data selection circuit 208. Based on the trace selection signal 217 disclosed above, the trace data selection circuit 208 switches the trace target from the link layer circuit 205 to the physical layer circuit 203. During the normal system operation, in response to detection of an error by the link layer circuit error detection unit 206, a link layer error report signal 223 is sent to the trace target determination unit 212. Since basically the link layer trace data bus 214 has already been selected during the normal system operation, the link layer circuit 205 is traced without change.

In response to the report of the error occurrence, the service processor 106 directs the read/write control circuit 210 to stop writing the trace data and reads the trace data from the trace data memory 209 through the read trace data bus 216. Failure analysis is performed by using the trace data that has been read so that a suspected error location is capable of being identified.

As disclosed above, the trace target is switched by the trace data selection circuit 208 upon occurrence of the error so that an error occurrence location is capable of being traced at the timing of the error detection. Since it takes a certain time until the data on the trace data bus 215 reaches the trace data memory 209, collection of desired trace data may be achieved by switching the trace target immediately after the error occurrence.

Note that, it is configured that, in storing the trace data in the trace data memory 209, a piece of information by which the trace target is indicated is attached thereto and the data is written based on control by the read/write control circuit 210. The data format of the trace data memory 209 will be disclosed below.

The switching of the trace targets from the initialization to the normal system operation will be disclosed with reference to FIG. 3.

A variety of settings are made after the power activation (indicated as “Power On” in FIG. 3). The settings of the trace data collection are made along with the above various settings. In other words, for example, a signal indicating Mode 0 is sent as the mode switching direction signal 219 from the service processor 106 to the trace mode register 211.

Then, the physical layer circuit 203 becomes a trace target during the initialization, and the link layer circuit 205 becomes a trace target after completion of the initialization. Note that the trace target during the normal system operation after completion of the initialization is not only the link layer circuit 205. Approximately ten (10) percent of all the trace data is still associated with the physical layer circuit as the trace target. This configuration is incorporated, in advance, as hardware.

As to the trace modes that are set along with the settings for the trace data collection in FIG. 3, six (6) modes, that is, Mode 0 through Mode 5 are prepared in the embodiment. Hereinafter, detailed descriptions of respective modes will be disclosed.

Mode 0: the trace target of Mode 0 during the system initialization is the physical layer circuit 203 and the trace target of Mode 0 after completion of the initialization is the link layer circuit 205.

Mode 1: the trace target of Mode 1 is an input interface part in the link layer circuit 205.

Mode 2: the trace target of Mode 2 is an output interface part in the link layer circuit 205.

Mode 3: the trace target of Mode 3 is an input/output packet in the link layer circuit 205.

Mode 4: the trace target of Mode 4 is the control signal in association with the physical layer circuit 203 and the link layer circuit 205 and a SMBUS signal (that is, control signals from the service processor 106).

Mode 5: the trace target of Mode 5 is the physical layer circuit 203.

As disclosed above, six (6) modes are prepared. After the power activation of the information processing apparatus and the like, tracing in one of the above disclosed modes set based on the mode switching direction signal 219 from the service processor 106 is performed at the timing of the settings of the trace data collection illustrated in FIG. 3.

Typically, the service processor 106 starts the initialization by setting the mode to Mode 0. As disclosed above, the physical layer circuit 203 becomes the trace target during the initialization, and the trace target is switched to the link layer circuit 205 after completion of the initialization when Mode 0 is selected.

Modes 1, 2, 3, and 5 are the modes that are used in collecting the trace data by limiting the trace targets in advance (for example, trace data is intensively collected from suspicious locations), e.g., for tests that reproduce errors, and so on. First, The value having been set for the trace mode register 211 is changed by the service processor 106 or an external setting unit, then the information processing apparatus is set up, thereafter use of the above modes is possible. For example, when Mode 1 or Mode 2 is specified, the trace target is limited to the input/output interface part to the LSI 200 inside the link layer circuit 205. When Mode 3 is specified, the trace target is limited to transmission packets transferred inside the link layer circuit 205. When Mode 5 is specified, the trace target is limited to the physical layer circuit 203.

Since Mode 4 is the mode whose trace target is the control signals and the SMBUS signal from the service processor 106 or the like, Mode 4 is used for checking the value set for the trace mode register 211 during the initialization in response to a failure of the system initialization or the like. When the system initialization fails to reproduce a failure in system initialization, the value set for the trace mode register 211 is changed and the system is set up, thereafter use of the Mode 4 is possible.

Since each of the LSIs is provided with the trace circuit 207 that includes the trace mode register 211, in the information processing apparatus having the plurality of LSIs therein, monitoring and control by the service processor 106 is possible even if the event timing of each of the LSIs is not coincident with each other, by virtue of the above mode settings.

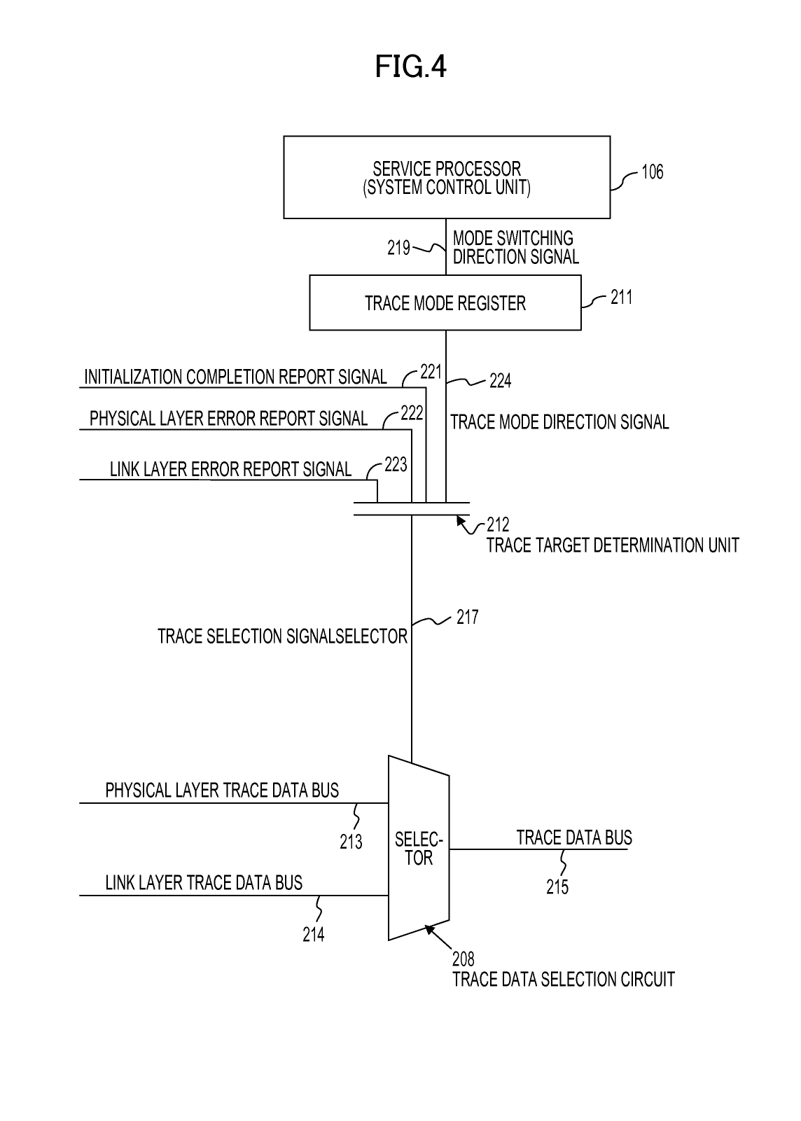

Next, the part that provides a function of switching the trace targets of the trace circuit 207 will be disclosed with reference to FIG. 4.

The trace target determination unit 212 receives a trace mode direction signal 224, the initialization completion report signal 221, the physical layer error report signal 222 from the physical layer, and the link layer error report signal 223 from the link layer. The trace mode direction signal 224 is a signal that is input from the service processor 106 to the trace target determination unit 212 based on the value set for the trace mode register 211. The trace target determination unit 212 determines whether the trace data from the physical layer circuit 203 or from the link layer circuit 205 is collected based on the trace mode direction signal 224, the initialization completion report signal 221, the physical layer error report signal 222, and the link layer error report signal 223, generates the trace selection signal 217 as the signal for switching the trace targets, and outputs the generated trace selection signal 217 to a selector in the trace data selection circuit 208. The trace data selection circuit 208 selects either the physical layer trace data bus 213 or the link layer trace data bus 214 based on the trace selection signal 217 to output to the trace data memory 209 through the trace data bus 215.

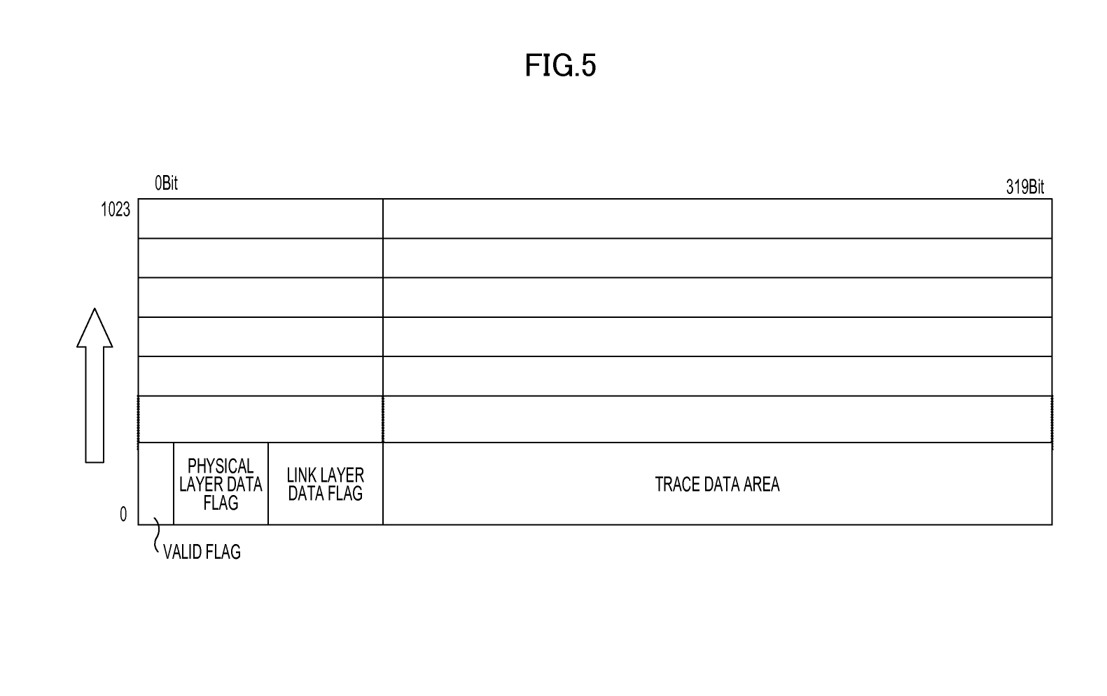

FIG. 5 is a diagram depicting a memory format of the trace data memory 209.

A valid flag indicates whether the trace data is valid or not.

A physical layer data flag indicates that the data stored in a trace data area is the trace data from the physical layer.

A link layer data flag indicates that the data stored in the trace data area is the trace data from the link layer.

When the trace data selection circuit 208 selects either the physical layer trace data bus 213 or the link layer trace data bus 214 to output to the trace data bus 215, data of the valid flag, the physical layer data flag, and the link layer data flag is attached to the trace data and sent to the trace data memory 209.

The trace data area is an area in which the trace data is stored.

As illustrated in FIG. 5, since the location of where a log was collected from may be distinguished depending on which one of the physical layer data flag and the link layer data flag is recorded, it is advantageous to identify the location where a failure has occurred in the failure analysis processing.

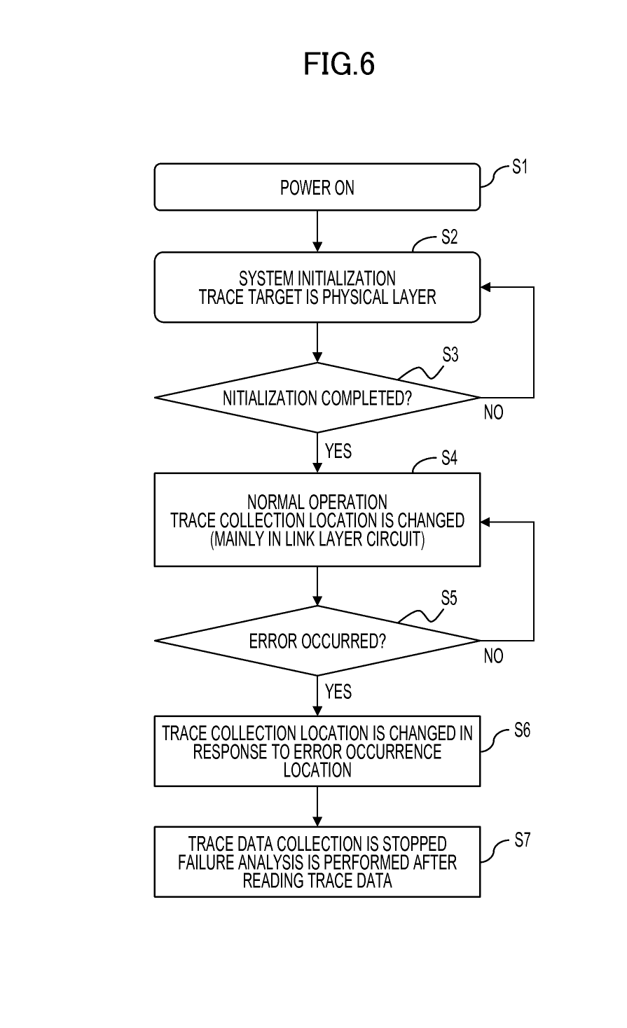

As hereinbefore disclosed, the embodiment is explained, and a process flow of the embodiment will be disclosed with reference to FIG. 6. Note here that the mode is set to Mode 0.

First, power activation of the information processing apparatus (indicated as “POWER ON” in FIG. 6) is performed in Operation S1.

Next, the system initialization is started in Operation S2. The trace data is collected from the physical layer circuit 203 during the initialization.

A determination is made of whether or not the initialization has completed in Operation S3. When the initialization has not been completed (NO), the process returns to Operation S2 to continue tracing the physical layer circuit 203. Upon completion of the initialization (YES), the process proceeds to Operation S4.

The system is brought into the normal system operation in Operation S4. The trace data is collected from the link layer circuit 205 during the normal system operation.

A determination is made of whether or not an error or a failure has occurred in the transmission circuit in Operation S5. When no error has occurred (NO), the process returns to Operation S4 to continue tracing the link layer circuit 205. When an error has occurred (YES), the process proceeds to Operation S6.

The trace target is changed in response to the location where the error has occurred in Operation S6. In other words, when it is detected that the error has occurred in the physical layer circuit 203, the trace target is switched to the physical layer circuit 203. On the other hand, when it is detected that the error has occurred in the link layer circuit 205, the trace target is switched to the link layer circuit 205.

The service processor 106 stops tracing after Operation S6. The writing is stopped based on a read/write direction signal 220 from the service processor 106, and a signal based on which the reading is started is sent to the read/write control circuit 210. The read/write control circuit 210 stops the writing to the trace data memory 209 and starts the data reading according to a read/write control signal 218.

As hereinbefore disclosed, the embodiment is explained in detail.

According to the embodiment, the physical layer circuit becomes the trace target during the system initialization, and on the other hand, the link layer circuit becomes the trace target during the normal system operation, so that the trace data collection dynamically switches therebetween. Furthermore, in response to the occurrence of an error, the trace target may be appropriately switched depending on the state of the system and on the location where the error has occurred.

Thus, an increase in the amount of trace data may be reduced by switching the trace target responsive to the operating state of the system and the location where the error has occurred. Since it is possible to reduce the increase in the amount of trace data, capacity of the trace data memory storing the trace data may be economized. In other words, this may prevent an increase in the amount of hardware. In consequence, it is possible to reduce if not prevent a cost increase due to the increase in the amount of hardware. In addition, the reduction in the amount of trace data makes it possible to reduce failure analysis processing time. Furthermore, since the location (trace target) of where the trace data was collected from is recorded along with the trace data in storing the collected trace data in the trace data memory, it is also possible to improve efficiency in the failure analysis processing therewith.

As disclosed hereinbefore, the embodiment is explained in detail. The present invention is not limited to the embodiment disclosed above. The trace target in the embodiment is the physical layer circuit and the link layer circuit. However, more than two trace targets are possible. In addition, it has been a problem that identification of an error on a transmission path between/among LSIs is difficult with tests at the factory shipment stage. To find such error on the transmission path between and/or among the LSIs, it is also possible to implement the present invention as follows, that is, an interface between and/or among the transmission paths or the like is used as the trace target. Moreover, the trace targets reside in the same LSI in the embodiment. However, the present invention is not limited thereto, and the trace targets may reside at any locations inside the system that includes the LSIs therein. Thus, various modifications, additions, substitutions or the like may be made without departing from the spirit and scope of the present invention.

What is claimed is:

1. A trace device for tracing data in an LSI, the trace device comprising:
a trace data storing unit that stores trace data;
a trace target determination unit that determines whether to store trace data of one of a plurality of trace targets in the trace data storing unit based on an operating state of a system including the LSI and based on a failure occurrence report reported from any of the trace targets in response to an occurrence of an error in the trace target residing in the LSI; and
a trace target selection unit that selects the trace data to be stored in the trace data storing unit out of the trace data from the plurality of trace targets based on the determining by the trace target determination unit, and stores the selected trace data in the trace data storing unit.

2. The trace device according to claim 1, wherein the trace target includes a physical layer circuit controlling a physical layer of a transmission and a link layer circuit controlling a link layer of a transmission in the LSI, and the failure occurrence report is reported to the trace target determination unit from one of the physical layer circuit and the link layer circuit.

3. The trace device according to claim 2, wherein the operating state includes an initialization period of the system and a normal operation period of the system.

4. The trace device according to claim 3, wherein the trace target determination unit conducts a first determination of the physical layer circuit as the trace target in response to one of the initialization period and a receipt of the failure occurrence report by a physical layer circuit error detection unit, conducts a second determination of the link layer circuit as the trace target in response to one of the normal operation period and a receipt of the failure occurrence report by a link layer circuit error detection unit, generates a signal selecting the trace target based on one of the first determination and the second determination, and sends the signal to the trace target selection unit.

5. The trace device according to claim 4, wherein the trace target selection unit selects a data bus for outputting the trace data from the plurality of trace targets, based on the signal sent from the trace target determination unit.

6. The trace device according to claim 1, wherein a flag that indicates from which of the trace targets the trace data is collected is attached to the trace data and the trace data is stored in the trace data storing unit, when the trace data is stored in the trace data storing unit.

7. The trace device according to claim 1, wherein storing the trace data in the trace data storing unit is stopped and the trace data is read out from the trace data storing unit in response to the occurrence of an error.

8. An information processing apparatus which includes an LSI on which tracing is performed, the LSI comprising:
a trace data storing unit that stores trace data;
a plurality of trace targets handling data;
a failure detection unit that is included in each of the trace targets and that detects an occurrence of a failure in each of the trace targets;
a trace target determination unit that determines whether to store trace data of one of the trace targets in the trace data storing unit based on an operating state of the information processing apparatus and based on a failure occurrence report reported by the failure detection unit; and
a trace target selection unit that selects the trace data to be stored in the trace data storing unit out of the trace data from the plurality of trace targets based on the determining by the trace target determination unit and stores the selected trace data in the trace data storing unit.

9. The information processing apparatus according to claim 8, wherein the trace target includes a physical layer circuit controlling a physical layer of a transmission and a link layer circuit controlling a link layer of a transmission in the LSI, and the failure detection unit is a physical layer circuit error detection unit and a link layer circuit error detection unit.

10. The information processing apparatus according to claim 9, wherein the operating state includes an initialization period of the system and a normal operation period of the system.

11. The information processing apparatus according to claim 10, wherein the trace target determination unit conducts a first determination of the physical layer circuit as the trace target in response to one of the initialization period and a receipt of the failure occurrence report by the physical layer circuit error detection unit, conducts a second determination of the link layer circuit as the trace target in response to one of the normal operation period and a receipt of the failure occurrence report by the link layer circuit error detection unit, generates a signal selecting the trace target based on one of the first determination and the second determination, and sends the signal to the trace target selection unit.

12. The information processing apparatus according to claim 11, wherein the trace target selection unit is a selection circuit that selects a data bus output from the plurality of trace targets based on the signal sent from the trace target determination unit.

13. The information processing apparatus according to claim 8, wherein a flag that indicates from which of the trace targets the trace data is collected is attached to the trace data and the trace data is stored in the trace data storing unit, when the trace data is stored in the trace data storing unit.

14. The information processing apparatus according to claim 8, wherein storing the trace data in the trace data storing unit is stopped and the trace data stored in the trace data storing unit is read out from the trace data storing unit in response to the occurrence of an error.

15. A trace method for tracing data in an LSI, the method comprising:
detecting occurrence of a failure in each of a plurality of trace targets;
determining whether to store trace data of one of a plurality of trace targets in a trace data memory based on an operating state of a system including the LSI and based on the detecting the occurrence of the failure; and
selecting the trace data to be stored in the trace data memory out of the trace data from the trace targets based on the determining and storing the selected trace data in the trace data memory.

16. The trace method according to claim 15, wherein the trace target includes a physical layer circuit controlling a physical layer of a transmission and a link layer circuit controlling a link layer of a transmission in the LSI.

17. The trace method according to claim 16, wherein the operating state includes an initialization period of the system and a normal operation period of the system.

18. The trace method according to claim 17, further comprising:
determining the physical layer circuit as the trace target in response to one of the initialization period and the detecting the failure in the physical layer circuit; and
determining the link layer circuit as the trace target in response to one of the normal operation period and the detecting the failure in the link layer circuit.
